(19) United States
(12) Patent Application Publication
(10) Pub. No.: US 2009/0033628 A1
(43) Pub. Date: Feb. 5, 2009

(54) METHOD AND SYSTEMS FOR REVEALING FUNCTION ASSIGNMENTS ON FIXED KEYPADS

(76) Inventor: Aditya Narain SRIVASTAVA, Fremont, CA (US)

Correspondence Address: QUALCOMM INCORPORATED, 5775 MOREHOUSE DR., SAN DIEGO, CA, 92121, US

(21) Appl. No.: 12/139,845

(22) Filed: Jun. 16, 2008

Related U.S. Application Data
(60) Provisional application No. 60/950,112, filed on Jul. 16, 2007.

(51) Int. Cl. G06F 3/02; H03K 17/94

(52) U.S. Cl. 345/169; 341/22

(57) ABSTRACT

Methods and computing devices provide the capability of revealing the value or function assigned to particular keys in a keypad or keyboard by an application running on a computing device. A touch or near touch of a key prompts the presentation or display of the value or function presently assigned to the touched or nearly touched key. The key function assignment may be presented in a portion of the display so as to not block other graphics and text in the display. The process for generating a display of the function or value assigned to a touched or nearly touched key may be performed by a keypad protocol receiving key configurations from the application.

### RELATED APPLICATIONS

The present application claims the benefit of priority to U.S. Provisional Patent Application No. 60/950,112 filed Jul. 16, 2007 entitled “Dynamically Configurable Keypad,” the entire contents of which are hereby incorporated by reference.

### FIELD OF THE INVENTION

The present invention relates generally to mobile computer systems, and more particularly to methods and systems for revealing functions assigned to particular keys on mobile devices such as cellular telephones.

### BACKGROUND

The usage of mobile electronic devices (mobile devices), such as cellular telephones, is ever increasing due to their portability, connectivity and ever increasing computing power. As mobile devices grow in sophistication, the variety and sophistication of application software is increasing, turning mobile devices into multipurpose productivity tools. Yet, the usefulness of mobile devices and their applications are limited by the small area available for the user-interface. Traditional cellular telephones included a simple keypad of fixed configuration. To provide more functionality for mobile devices having fixed keypads, application software frequently assigns functions to the keys which differ from the label on the key (e.g., 1, 2, etc.). However, this solution may leave users unsure about the functionality assigned to each key.

### SUMMARY

Various embodiment systems and methods reveal a value or function assigned to a key of a computing device based on the position of the user's finger or a pointing device on or near the key. Application software running on the computing device determines the current meaning, or value or function assigned to the key. The meaning of the key is presented in a portion of the display area. The current meaning of the key may be managed by a keypad protocol operating as part of the system software. Applications control the description of the key function or value defining the current meaning of the key that is presented on the display in response to the key being touched or nearly touched.

### BRIEF DESCRIPTION OF THE DRAWINGS

The accompanying drawings, which are incorporated herein and constitute part of this specification, illustrate exemplary embodiments of the invention, and, together with the general description given above and the detailed description given below, serve to explain features of the invention.

FIG. 1 is a component block diagram of a typical cell phone usable with the various embodiments.

FIGS. 2A and 2B are a cross-sectional side and a top view, respectively, of an embodiment of a touch-sensitive keypad.

FIG. 3 is a cross-sectional view of another embodiment of a touch-sensitive keypad.

FIG. 4 is a hardware/software architecture diagram of a standard prior art cell phone.

FIG. 5 is a process flow diagram of an embodiment.

FIG. 6 is a message flow diagram of messages associated with the process steps illustrated in FIG. 5.

FIG. 7 is a hardware/software architecture diagram of an embodiment.

FIG. 8 is a process flow diagram of a portion of the functionality enabled by an embodiment.

FIG. 9 is a message flow diagram of messages associated with the process steps illustrated in FIG. 8.

FIG. 10 is a process flow diagram of a portion of the functionality of an embodiment.

FIG. 11 is a data structure suitable for use in an embodiment.

FIG. 12 is a data structure for a key translation table according to an embodiment.

FIG. 13 is a process flow diagram of a portion of the functionality of an embodiment.

FIG. 14 is a data structure of a key press event interrupt according to an embodiment.

FIG. 15 is a process flow diagram of a portion of the functionality of an embodiment.

FIG. 16 is a message flow diagram of messages associated with the process steps illustrated in FIG. 15.

FIGS. 17 and 18 are illustrations of a mobile device implementing an embodiment to reveal alternative fonts assigned to keypad keys.

FIG. 19 is an illustration of a conventional cell phone with a media player application operating.

FIGS. 20 and 21 are illustrations of a cell phone employing an embodiment to reveal functionality assigned to a key by a media player application.

FIG. 22 is an illustration of a conventional cell phone with a game application operating.

FIGS. 23-25 are illustrations of a cell phone employing an embodiment to reveal functionality assigned to a key by a game application.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

In this description, the term “exemplary” is used herein to mean “serving as an example, instance, or illustration.” Any implementation described herein as “exemplary” is not necessarily to be construed as preferred or advantageous over other implementations.

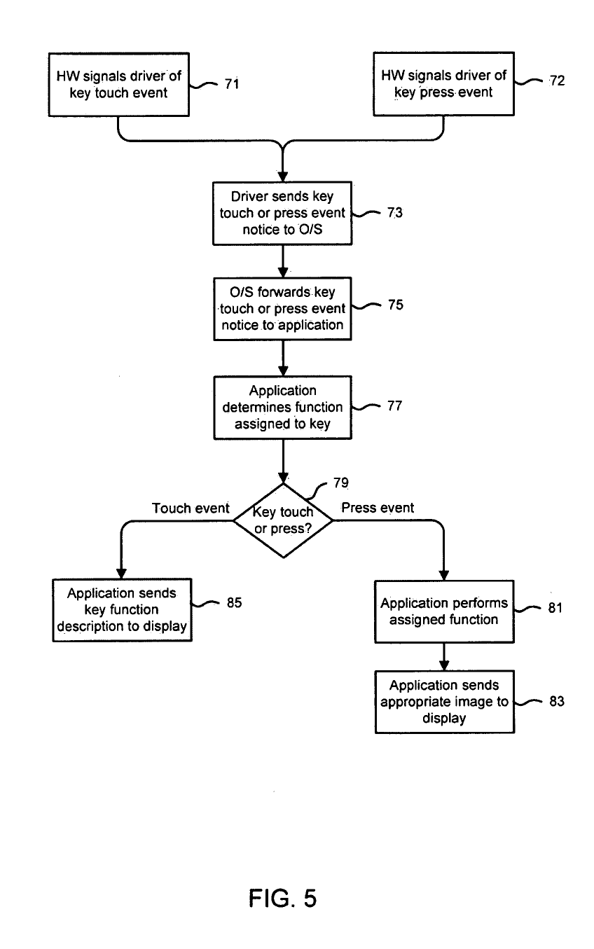

As used herein, the term “computing device” refers to any programmable computer device including a display and a keyboard or keypad. In description of the embodiments, reference is made to “mobile devices” which are but one type of computing device that implements the various embodiments. As used herein, the terms “mobile handsets” and “mobile devices” are used interchangeably and refer to any one of various cellular telephones, personal data assistants (PDA's), palm-top computers, laptop computers with wireless modems, wireless electronic mail receivers (e.g., the Blackberry® and Treo® devices), cellular telephones, and multimedia Internet enabled cellular telephones (e.g., the iPhone®), and similar computing devices. A mobile device may include a programmable processor and memory as described more fully below with reference to FIG. 4. In a preferred embodiment, the mobile device is a cellular handheld device (e.g., a cellphone), which can communicate via a cellular telephone network. However, the references to a mobile device in the following descriptions is not intended to exclude other forms of computing devices, which may include, for example, personal computers, laptop computers, computer terminals, game console terminals, and work stations.

As used herein, the term “keypad” refers to any of a variety of user interfaces in which a user presses a button or key in order to communicate to a mobile device that a function associated with the key should be implemented. Examples of keypads encompassed within the following description include the number keypads of conventional cellular telephones, miniature keyboards and is implemented on a variety of mobile devices, external keypads and keyboards which may be electronically coupled to a mobile device (e.g., via a wired or wireless data link), computer keyboards, and musical keyboards which may be coupled to a personal computer, mobile device or other computing device. For ease of description, the figures depict and the descriptions refer to the keypad of a typical cellular telephone. However, these descriptions and illustrations are for example only, and are not intended to limit the scope of the description or the claims to a particular keypad configuration.

As used herein, the term “touch” and “touch-sensitive” are intended to encompass close proximity as well as actual physical touching of a key. The “touch-sensitive” keypads described herein may also (or alternatively) be able to sense close proximity of a finger, stylus or other object. Thus, the use of “touch” and “touch-sensitive” in the following description should not be interpreted as being limited to requiring physical touching or as excluding close-proximity sensitive keypads. As used herein, the term “near touch” refers to a close proximity event, as when a user brings a finger into close proximity with a close-proximity sensitive key.

The various embodiments enable a mobile device to sense the close proximity or touch of a user's finger or stylus to a key and display for the user a description of the function assigned to a particular key by application. By displaying the function assigned to a key without requiring the user to press the key, mobile device applications can assign a variety of different functions to keys on a fixed keypad without requiring users to memorize the function assignments and without having to block the display with a menu of key-function assignments. The various embodiments may be useful in applications which use a fixed keypad to receive commands that are inconsistent with the value printed on the keys (e.g., “1,” “2,” “3”, etc.). Additionally, the embodiments enable mobile devices to implement alphabets and number formats different from those printed on the keys while providing users with a handy mechanism for locating desired keys in their native language. The embodiments may also be useful for mobile devices that include keypads which have application-assignable keys, such as the function keys on a conventional computer keyboard.

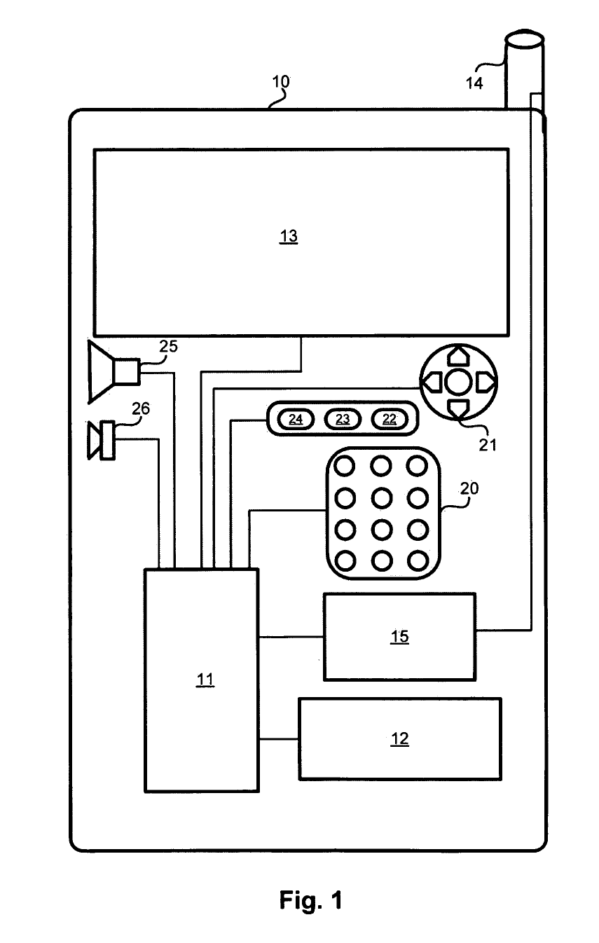

The embodiments described herein may be implemented on any of a variety of mobile devices. Typically, such mobile devices will have in common the components illustrated in FIG. 1. For example, the mobile device 10 may include a processor 11 coupled to internal memory 12 and a display 13. Additionally, the mobile device 10 will have an antenna 14 for sending and receiving electromagnetic radiation that is connected to a wireless data link and/or cellular telephone transceiver 15 coupled to the processor 11. In some implementations, the transceiver 15 and portions of the processor 11 and memory 12 used for cellular telephone communications are collectively referred to as the air interface since it provides a data interface via a wireless data link. Mobile device 10 also typically include a keypad 20 or miniature keyboard and menu selection buttons or rocker switches 21 for receiving user inputs, and may include application-programmable buttons 22, 23, 24.

In an embodiment, a mobile device includes a keypad that is configured to sense the touch or close proximity of a finger, stylus or other pointing device. A variety of sensors can be used to sense the touch or close proximity of a finger, stylus or other pointing device to a key. Such sensors may include, for example, electrical property sensors (e.g., capacitance, inductance or voltage), thermal sensors (e.g., capable of detecting the temperature of a finger in close proximity to the key), light sensors (e.g., to detect a shadow cast by a finger or pointing device covering the key), and pressure sensors (e.g., to detect the light touch of a finger or pointing device). The touch-sensitive keypad is configured to provide a signal to the mobile device processor 11 that indicates when a particular key is touched that is different from the signal indicating that the key has been pressed. By sensing the touch or close proximity of a finger or stylus to a key, the mobile device can be configured with software to provide a display showing the function presently assigned to the particular key before the key is pressed. Such a display may be presented in a portion of the mobile device display 13 that does not block other information and graphics on the display.

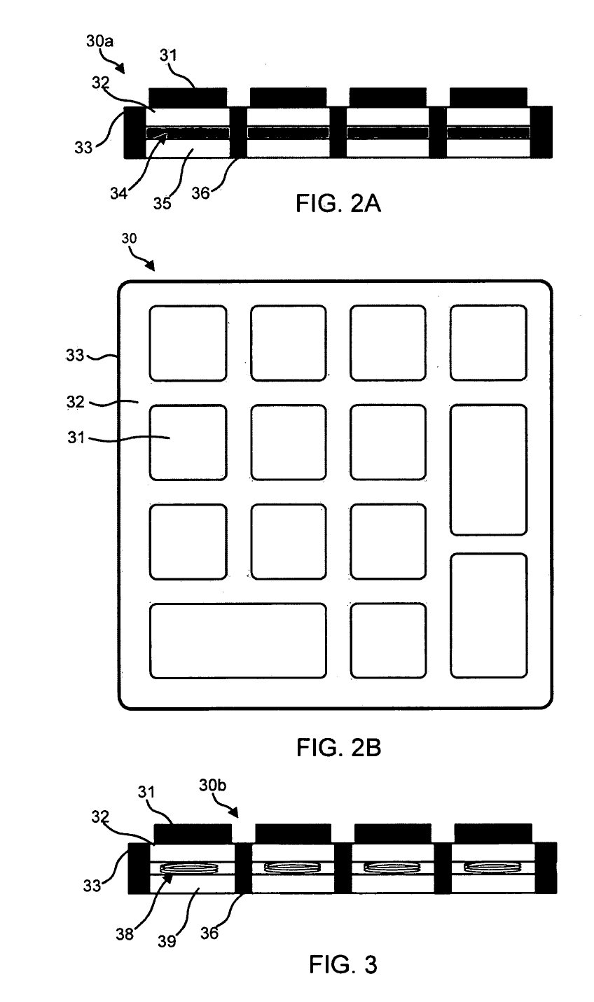

A touch-sensitive keypad is a user interface which has the capability of sensing both the touch and the press of a key as different kinds of events and can signal the key touch and keep press events to a processor 11. An example embodiment of a touch-sensitive keypad is illustrated in FIGS. 2A and 2B. In this example embodiment, a capacitor circuit associated with each key is used to sense when a finger or stylus is touching or in very close proximity to the key. The configuration of components associated with other electrical, thermal, light and pressure sensors would appear similar if separately diagrammed.

Referring to FIG. 2A, such a keypad 30 includes a plurality of individual keys 31 which are supported by and mechanically coupled to a press sensing circuit assembly 32. The press sensing circuit assembly 32 may be any of a variety of well-known keypad mechanisms which can detect the movement or press of a key 31 and convert that event into an electrical signal that can be interpreted by a processor. For example, the press sensing circuit assembly 32 may include a switch that is closed upon a press of the key 31 so that voltage transmitted through the closed-circuit can be received by another circuit or processor which can interpret the voltage as indicating that the key 31 has been pressed. Alternatively, the press sensing assembly circuit 32 may sense the press of a key based upon a change in capacitance or resistance caused by the key movement working upon eye a capacitor or resister material. The press sensing circuit assembly 32 may include structural elements for supporting the key 31 and enabling the key to move through a distance of travel sufficient to allow a user to sense that the key has been successfully pressed.

Also associated with each key 31 is a touch or near-touch sensing circuit 34, such as a capacitor or a capacitance sensor. A capacitance sensor circuit 34 is a circuit which can detect a change in capacitance as may occur when a user touches or nearly touches a key 31, thereby adding their body to the electrostatic materials that comprises a capacitor assembly between the key 31 and a bottom support 35. In another embodiment, the touch sensing circuit 34 may be a low-voltage detection circuit which can sense the voltage passed to a key 31 from a user's body when a finger is brought into close proximity or touches the key 31. In another embodiment, the touch sensing circuit 34 may be a thermal or temperature sensing circuit that is sensitive enough to detect a change in temperature that occurs when a user's finger touches or comes in close proximity to the key 31. In further embodiment, the touch sensing circuit 34 may be a light sensing circuit that can detect a change in light through the key 31 that occurs when a user's finger shades the key as when it touches or comes in close proximity to the key 31. These alternative embodiments are not separately illustrated since when diagrammed as a circuit block a voltage, thermal, temperature or light sensing circuit would appear the same as the capacitance sensor 34 illustrated in FIG. 2A.

The touch-sensitive keypad 30 may also include a side support structures 33 (which may be made of an insulator material) and electrical insulator material 36 between keys so as to electrically isolate each key 31 and touch sensing circuit 34 from one another. As illustrated in FIG. 2B, when viewed from above, a touch-sensitive keypad 30 may appear as any conventional keypad.

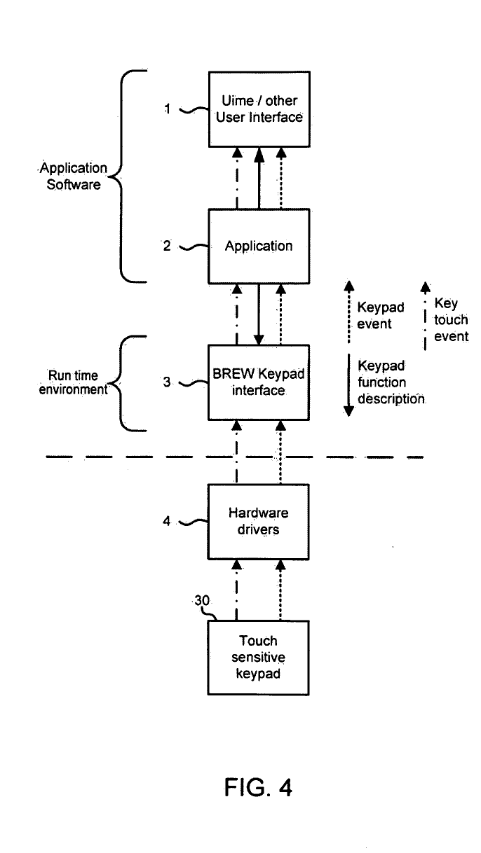

In another embodiment, illustrated in FIG. 3, the touch sensing circuit includes an inductance sensors 38 which can sense the change in inductance between the key 31 and a bottom support 39 occurs when a user's finger or stylists touches or comes into close proximity with the key 31. For example, the inductance sensor 38 may be in the form of coil coupled to add an inductance sensing circuit which is configured to sense the change in inductance through the coil when a user's finger is nearby. An inductance based touch-sensitive keypad 37 may also include side support structure 33 and intern-key insulator material 36 in order to isolate the keypad electrically from the mobile handset and isolate each key one from another.

As with any keypad, circuits will be included for routing signals received from the keypress sensor circuit 32 and from the touch sensing circuit 34, 38 to external circuits and ultimately to the processor of the mobile device. Any of the keypad circuitry known in the art may be implemented for this purpose, and so are not included in the figures.

In a preferred embodiment, the touch-sensitive keypad 30 is built into the mobile device 10 as its primary keypad (i.e., replacing the conventional keypad 20 illustrated in FIG. 1). However, the embodiments and the scope of the claims are not limited to a mobile device including such a touch-sensitive keypad 30. The embodiments encompass any computing device which is coupled to a touch-sensitive keypad or keyboard and configured with software which accomplish methods consistent with the embodiments. For example, in an embodiment the processor and display are part of a personal computer which is coupled to a keyboard having a touch-sensitive keys, such as touch-sensitive function keys F1 through F12. As another example, a mobile device 10 may be coupled to a separate touch-sensitive keypad by a data cable or wireless data link.

Traditionally, keypads function by transforming the depression of a key 31 into an electrical signal that can be interpreted by the mobile device and its application software. FIG. 4 illustrates a hardware/software architecture of a typical mobile device showing how key press events are communicated to application software. The pressing of a key on a touch-sensitive keypad 30 closes a circuit or changes a capacitance or resistance that results in an electrical signal that can be processed by a hardware driver 4. The hardware driver 4 may be circuitry, software or a mixture of hardware and software depending upon the particular mobile device. The hardware driver 4 converts the electrical signal received from the keypad 5 into a format that can be interpreted by a software application 2 running on the mobile device. This signal may be in the form of an interrupted or stored value in a memory table which is accessible by application software. Such an interrupted or stored value in memory may be received by a run time environment software layer 3, such as the Binary Runtime Environment for Wireless (BREW®) platform created by QUALCOMM®Incorporated, Windows Mobile® and Linux®. The run time environment software layer 3 provides a common interface between application software and the mobile device. Thus, key press event signals (shown as dashed arrows) are passed on to the application 2 in the form of a key press event message. The application software 2 must be able to understand the meaning of the key press event, and therefore is written to accommodate the underlying hardware driver 4 and keypad hardware 30. Key press events may also be communicated to a user-interface layer 1 such as to display the value or function associated with a particular key.

In an embodiment, a user touching or nearly touching a key without pressing the key is sensed by the touch-sensitive keypad 30 and converted into a key touch event message (shown as dash and dot arrows) that is sent to the hardware driver 4. Key touch event messages may be transmitted via a runtime environment 3 to an application 2. Upon receiving a key touch event message, the application 2 determines the value or function assigned to the associated key (i.e., the key that is being touched or nearly touched), and directs the user interface 1 to display the associated value or function within the mobile device display 13 as described below.

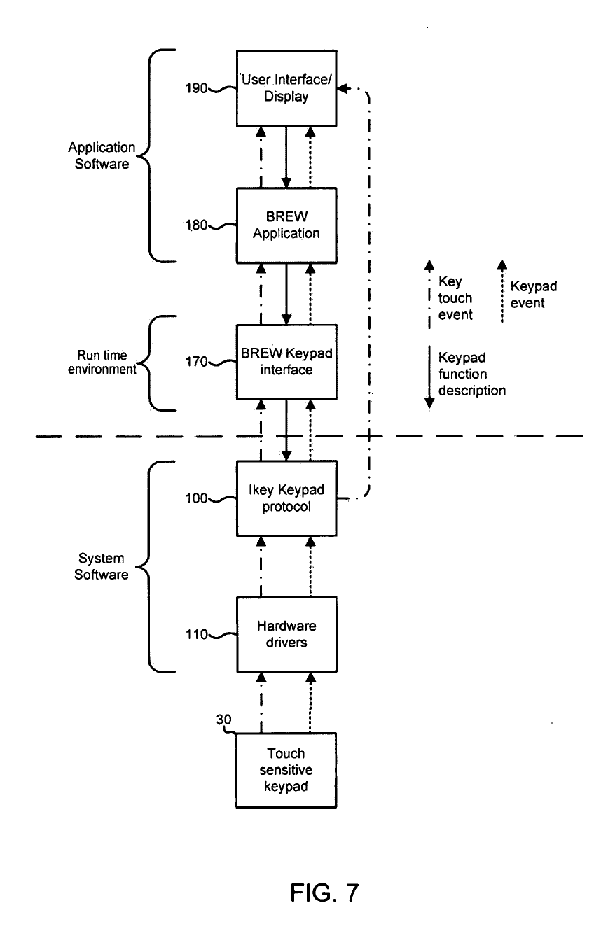

Information regarding a key touch event or a key press event may be communicated from the keypad 30 to the driver 4 and from the driver to be application 2 in a variety of data and signal structures as would be appreciated by one of skill in the art. An example of signals being passed among the various software layers is described below with reference to FIG. 6. Alternatively, the key touch and keypress event information may be may be stored in memory 12 in a register or state machine that is frequently checked by the operating system and/or application. For example, flags may be set in memory indicating that a key press event or key touch event has occurred and that the associated key identification (key ID) is in memory available for processing. In an embodiment, this notification may be accomplished by storing two flags and a key ID symbol and a known memory location or register. A first flag may indicate that an event has occurred that needs to be processed. A second flag may indicate whether the event is a key touch (e.g., the second flag is set to “0”) or a key press event (e.g., the second flag is set to “1”). The key ID symbol may be a simple data code identifying the particular key that has been touched (or nearly touched) or pressed. Thus, in a very small amount of memory, keypress and key touch events can be communicated to the operating system and applications.

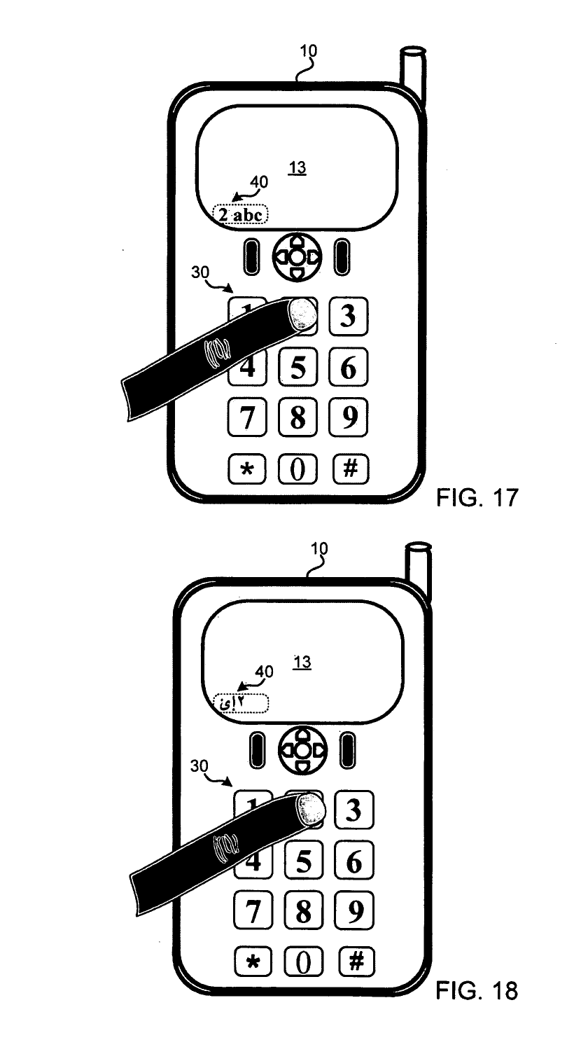

As another example, the keypad hardware 30 or the keypad driver software 4 may signal a key touch event or a key press event by sending a software interrupt to the runtime environment layer 3 or the application 2. An example of the data structure of such an interrupt is described below with reference to FIG. 14.

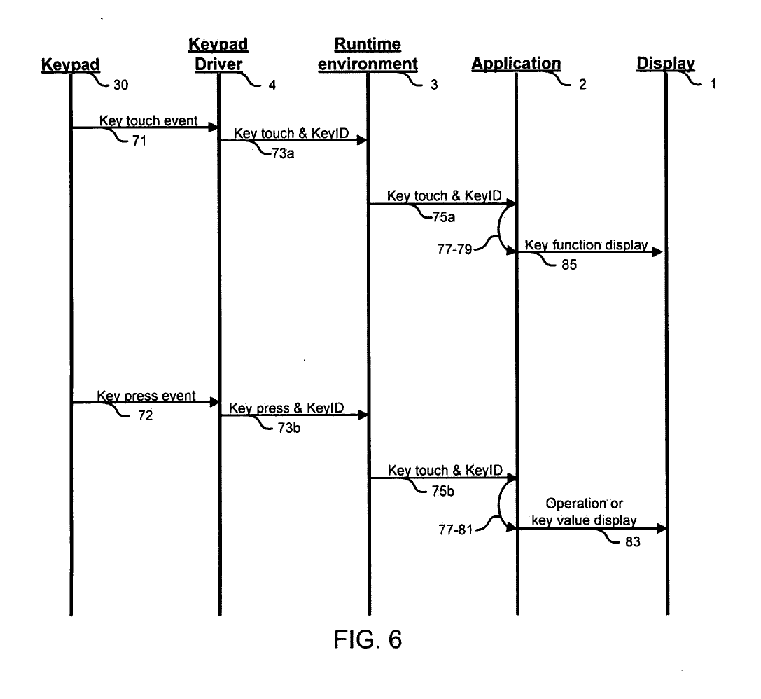

Example processing steps that may be performed upon a keypress or key touch event are illustrated in FIG. 5. When a user presses a key 31, the touch-sensitive keypad 30 senses when this event and sends a key press event electrical signal to the keypad driver, step 72. The keypad driver receives the keypress event signal from the keypad, recognizes the key that has been pressed and sends an appropriate keypress notification to the operating system or runtime environment later, step 73. The runtime environment layer forwards the keypress notification to the application, step 75. Upon receiving the keypress event notification, the application determines the function or value assigned to the particular key, step 77. The application may also determine whether the event was a keypress or a key touch event, test 79. Being a keypress event, the application performs the function assigned to the particular key, step 83, and sends the appropriate image or symbol to the display associated with the performed function, step 83.

When a user nearly touches or touches but does not press a key 31, the touch-sensitive keypad 30 senses when this touch event and sends a key touch event electrical signal to the keypad driver, step 71. The keypad driver receives the key touch event signal from the keypad, recognizes the key that has been pressed and sends an appropriate key touch notification to the operating system or runtime environment later, step 73. The runtime environment layer forwards the key touch notification to the application, step 75. Upon receiving the key touch event notification, the application determines the function or value assigned to the particular key, step 77. The application may also determine whether the event was a keypress or a key touch event, test 79. Being a key touch event, the application communicates to the display (or changes the image presented on the display to indicate) the value or function associated with the touched or nearly touched key, thereby informing the user of the value that will be entered or the function will be performed if the key is pressed.

The method steps illustrated in FIG. 5 may be accomplished in a series of data messages passed among the hardware and software layers of the mobile device 10, examples of which are illustrated in FIG. 6. When a key is nearly touched or touched but not pressed, the touch-sensitive keypad hardware 30 senses this event and sends an electrical signal to the keypad driver layer 4 informing it of a touch event and the particular key that has been touched, message 71. The keypad driver 4 translates this event into a signal which can be understood by the runtime environment layer 3, message 73a. This message informs the runtime environment layer 3 of both the nature of the event (i.e., a key touch event) and the particular key involved, such as by providing the key ID of the touched or nearly touched key. The runtime environment layer 3 then forwards the key touch event information to the application 2, message 75a. The application performs the processing of step 77-79 to determine the function associated with the touched or nearly touched key and sends a signal to the display 13 or reconfigures the display 13 to present the value or function associated with the key, message 85.

When a key is pressed, the touch-sensitive hardware 30 senses this event and sends an electrical signal to the keypad driver layer 4 informing it of a touch event and the particular key that has been touched or nearly touched, message 71. The keypad driver 4 translates this event into a signal which can be understood by the runtime environment layer 3, message 73a. This message informs the runtime environment layer 3 of both the nature of the event (i.e., a keypress event) and the particular key involved, such as by providing the key ID of the pressed key. The runtime environment layer 3 then forwards the keypress event information to the application 2, message 75a. The application performs the processing of steps 77-81 to determine or function (or value) associated with the touched or nearly touched key and then perform that function (or enter the value). Once the function has been performed (or the value entered), the application sends a signal to the display 13 or reconfigures the display 13 to present the results of the performed (or display the entered value), message 83.

In the foregoing description referencing FIGS. 5 and 6, key touch and keypress events are described as being communicated from the driver layer 4 to the application 2 by way of the runtime environment 3. However, in some implementations the driver layer 4 may communicate directly with the application 2. As a further alternative, the driver layer 4 of may communicate to the environment runtime environment layer 3 that a key event has occurred and then communicate the information regarding the key event directly to the application 2, such as by storing the key event information in a register accessible by the application 2.

In embodiments in which the key touch or keypress event is communicated by storing flags and a key ID in a register, the messages illustrated in FIG. 6 will be replaced by memory store and memory access operations that may be performed sequentially in a manner similar to the reception of the messages described above.

In order to implement these embodiments, the application software may be configured to recognize key touch events and interact with the mobile device display in order to reveal the value or function associated with the touched or nearly touched key. Such a configuration may be accomplished by adding additional processing steps that recognize a key touch event signal or registry value and present the assigned value or function to the display. Runtime environment layer software may also be adapted to recognize a key touch event and to appropriately notify applications of this event in a manner (e.g., a data format or flag values) different from that of a keypress event. Additionally, the hardware driver used with a touch-sensitive keypad will be configured to distinguish the two kinds of key events and to appropriately communicate key touch event and keypress event information to the runtime environment or the application.

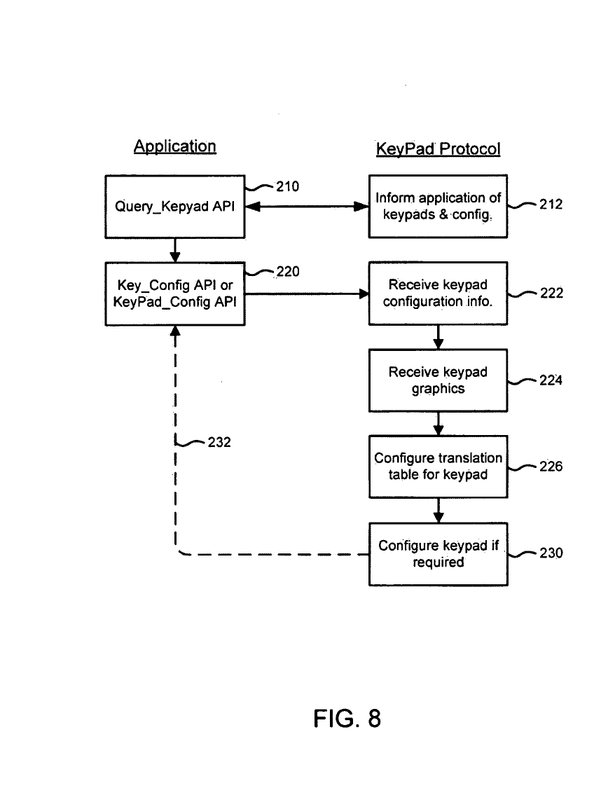

The added complexity required of the application software to distinguish and act upon key touch events versus keypress events may be avoided by implementing the various embodiments in conjunction with a keypad protocol layer within the operating system of the mobile device. Such a keypad protocol is described in U.S. patent application Ser. No. ______ entitled “Standardized Method and Systems for Interfacing with Configurable Keypads”, which is filed concurrently herewith, the entire contents of which are hereby incorporated by reference. The keypad protocol layer serves as an interface between application software and keypad drivers that enables application software to define keypad functions to the operating system and receive key event notifications in standard formats. By doing so, the process of displaying and assign a value or function of a touched or nearly touched key can be performed by the keypad protocol, removing the need for this processing from the application software. If a mobile device is equipped with a touch-sensitive keypad then this will be known to the keypad protocol layer which can communicate with the mobile device display to present the associated value or function that has been assigned by the application. In this manner, a software application can be written for a variety of mobile devices without having to accommodate the touch-sensitive keypad functionality described herein. The following description with reference to FIGS. 7 through 16 described embodiments which are implemented on mobile devices which include such a keypad protocol layer within their system software.

As illustrated in FIG. 7, the keypad protocol 100 serves as an interfacing software layer between application software 180 and the keypad 30. As illustrated, the keypad protocol 100 is provided as part of the system software linking to various hardware drivers 110 and to the run time environment software 170, such as the BREW® layer. The keypad protocol 100 may also interface with a variety of different keypads enabling application software to select and configure one among a number of available keypads. Key event signals are sent from a keypad 30 to the associated keypad hardware driver 110. The keypad driver 110 translates the key event electrical signal into a format that can be understood by the keypad protocol 100.

The keypad protocol 100 receives the key press event signal from the driver layer 110 and sends a keypress event notification to an application 180 in a standardized format that application developers can anticipate and accommodate with standard software instructions. In doing so, the keypad protocol 100 configures a key press event message, such as a notification object, which can be interpreted by the application 180. This configured key press event message/notification object may be passed to an application 180 through the runtime environment software layer 170. Alternatively, the keypad protocol 100 may communicate the key press event message/notification object directly to the application 180. The application 180 may also communicate the key press event to a user-interface layer 190 providing the display function. Alternatively, the keypad protocol 100 may communicate the key value or function directly to the user-interface layer 190 for presentation on the display 13.

Of particular advantage to the various embodiments of the present invention, the keypad protocol 100 can receive key function assignments and configuration commands from applications 180 allowing it to determine the value or function assigned to a particular key at any given moment. Values and functions assigned to various keys are defined by the application running on the mobile device depending upon the functions of that software. In some instances, the value or function assigned to a particular key will depend upon whether other keys are pressed previously or simultaneously (e.g., such as following the press of a “shift” or “alt” key). In other instances, the function assigned to a particular key will depend upon the current operation being performed by the application. For example, in a media player application, the same key may be used to stop and start the media play, with the “stop” functionality assigned to the key whenever the media is playing, and the “start” functionality assigned to the key whenever a media file is selected but not yet playing. Thus, the value or functionality assigned to a particular key is context dependent and may change frequently during the operation of an application. By simplifying application development while enabling dynamic functionality key assignments, an application may configure the keypad protocol to report each keypress event using a command associated with the implicated functionality or value, leaving the processing of the particular keypress event and context to the keypad protocol 100. For example, a media player application may configure the keypad protocol 100 to report a keypress event as a “play” function or a “stop” function depending upon the context of the keypress event as determined by the keypad protocol. Thus, the keypad protocol 100 may communicate with the application using function definitions that are convenient for the application developer. In such an implementation, the application may be unable to determine the value or function assigned to a particular key at any given instant, leaving that processing to the keypad protocol 100. Since the keypad protocol 100 is informed of the function or value assigned to a particular key, the protocol can communicate this information to the display in response to a key touch event. By allocating to the keypad protocol 100 the processing of key touch events and revealing the assigned value or functionality on the display, application software can be easier to develop and need not be configured to interrupt other processing in order to reveal key assignments.

The keypad protocol 100 can also receive graphics from the application associated with the value or function assigned to a particular key. Such graphics may be used in the value/function reveal display generated by the keypad protocol. For example, if the application supports foreign language letters and numerals, the graphics for such graphics may be provided by the application to the keypad protocol 100 so that they may be used when revealing the assigned value in the display. Similarly, if the application assigns functions to keys that can be represented graphically, such as an arrow to indicate “play” and two vertical bars to indicate “stop,” such graphics can be provided to the keypad protocol 100 and used to reveal the assigned functionality in the display instead of describing the function in text form. In situations where the mobile device has or is connected to graphic user interfaces, the keypad protocol 100 can use such graphic files to the configure user interface displayed the graphic.

As described above, the keypad protocol 100 can receive key touch events from the hardware driver 110 and communicate with the display 190 to reveal the function associated with a touched or nearly touched key. Alternatively and in some implementations, the keypad protocol 100 can also communicate key touch events to the application 180, such as by way of the runtime environment layer 170, if the application is configured to process key touch events. For example, some applications may be written for mobile devices having touch-sensitive keypads, and thus be able to receive the key touch event notification and communicate the associated value or function to the user interface display 190 in a manner similar to that described above with reference to FIG. 4.

The keypad protocol 100 may include a standard set of APIs that the application developer can utilize in developing applications software. Thus, the keypad protocol layer 100 can serve as a standard software interface for higher-level software. The keypad protocol 100 may also include software tailored to interface directly with keypad drivers 110 to enable it to identify the particular key that has been touched (or nearly touched) or pressed based on a key event signal received from the keypad driver 110. Since the nature of keypad functions and interface signals may vary dramatically among different types of keypads, the keypad controller layer 104 provides a software layer for accommodating such complexity and hiding the complexity from the application layer 180.

In order to inform the keypad protocol 100 of the function or value assigned to particular keys, the application 180 needs to be able to provide keypad definition commands and graphics. Such definition and graphic information can be provided by the application 180 to the keypad protocol 100 directly or by way of the runtime environment layer 170. Similarly, user-interface software 190 may provide keypad definition and graphic configuration information to the keypad protocol 100. The keypad protocol 100 then uses such definition and graphics information to determine the value or function assigned to each key in the keypad. The keypad protocol 100 may also provide keypad configuration commands to the keypad hardware driver 110.

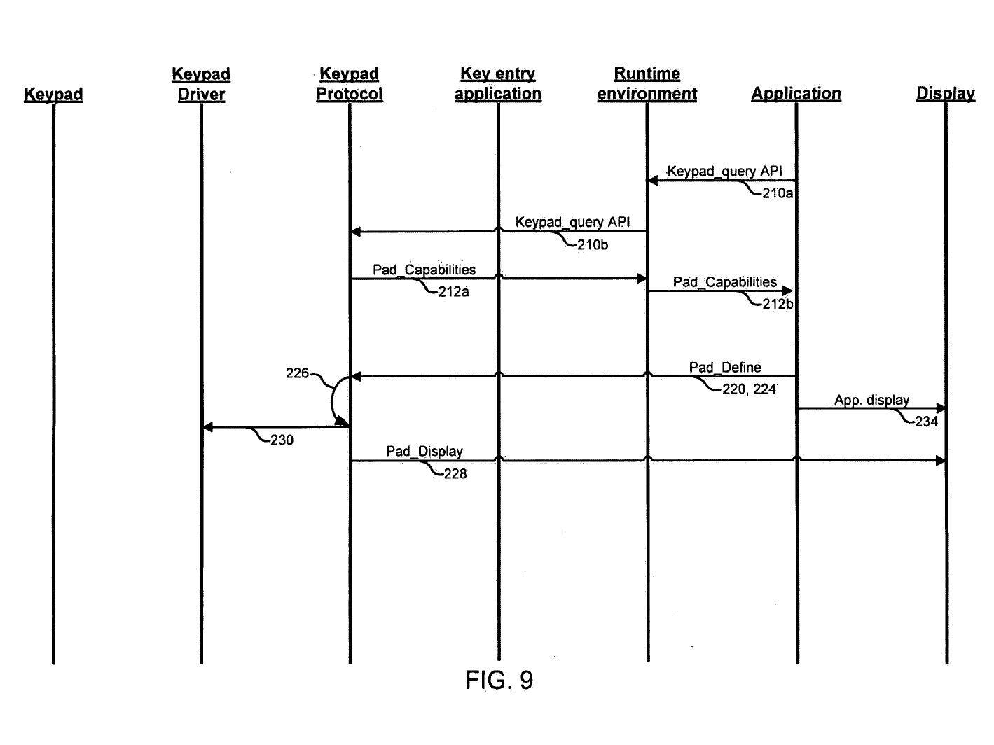

When an application 180 is first started, it may interact with the keypad protocol 100 in order to configure the keypad for operation consistent with the application's functionality. Example steps for this process are illustrated in FIG. 8. The keypad protocol 100 will be informed of the capabilities and configuration of the keypad integrated into the mobile device, and may also be informed of the capabilities and configuration of other keypads that may be coupled to the mobile device 10.

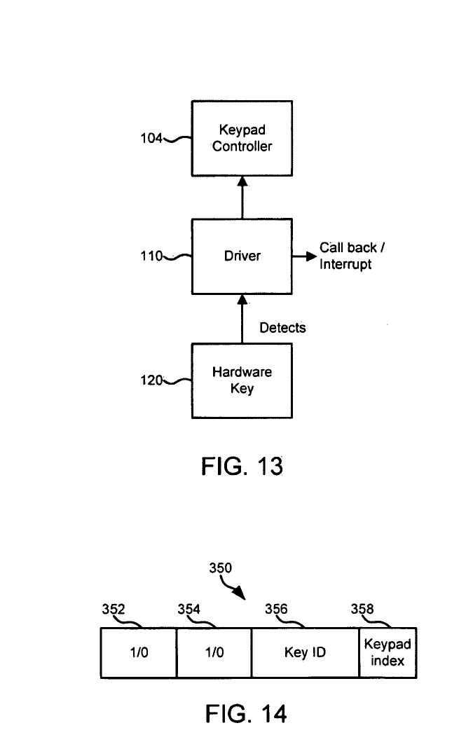

When an application 180 is loaded or otherwise needs to determine the available keypad and its capabilities (e.g., whether it is a touch-sensitive keypad), the application may ask for this information from the keypad protocol 100, such as by issuing an API, step 210. Even in situations where the mobile device has only one keypad, the application 180 may need to request information regarding the capabilities of the keypad since applications are typically written to operate on a variety of different types of mobile devices. For illustrative purposes, an example API entitled “Query_Keypad” is illustrated in the figures for performing this function. This API may simply ask the keypad protocol 100 to inform the application 180 of the keypads that are available for use as well as their various capabilities (e.g., configurable keypad or touchscreen). Upon receiving such a Query_Keypad API, the keypad protocol 100 may inform the application of the available (i.e., activated and connected) keypads and their capabilities, step 212. The format for informing the application of the available keypad(s) may be standardized in order to provide a common interface for application developers. The format of the information may be any suitable data structure, such as the data structure described below with reference to FIG. 11.

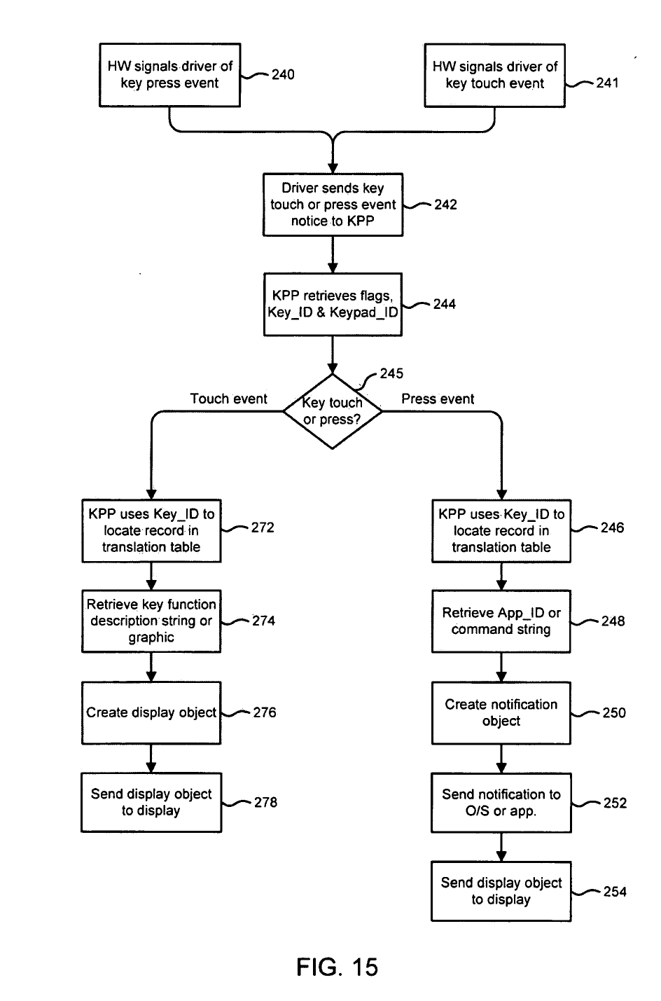

Upon receiving the keypad availability and configuration information, an application may provide configuration information to the keypad protocol, step 220. This configuration step may be in the form of an API to provide a common application interface for application developers. For illustrative purposes, example APIs entitled “Key_Config” and “Keypad_Config” are illustrated in the figures for performing this function. Such an API may specify the index number of the keypad and provide key configuration information on a key-by-key basis. Such configuration information may include the identifier that the application uses for a particular key event, a string describing the function or value assigned to the particular key or key event, and graphics information that can be used to display the key function in a graphical manner. An example format and content of such key-by-key configuration information is discussed below with reference to FIG. 12.

The keypad protocol 100 receives the keypad configuration information from the application 180, step 222 and any graphics files or images associated with the selected keypad, step 224. The keypad protocol 100 may configure a translation table associated with the keypad, step 226. Such a translation table can be used by the keypad protocol 100 to determine the appropriate command string or application key identifier to provide to an application 180 in response to each key press event. The keypad protocol 100 may also use the assigned value or function stored in the translation table to generate the display of the assigned value/function in response to a key touch event. Additionally, the keypad protocol 100 may further configure the keypad if required to match the functionality of the application, step 230. Upon completing the keypad configuration operations, the keypad protocol may inform the application 180 that the keypad is ready for operation, reply 232.

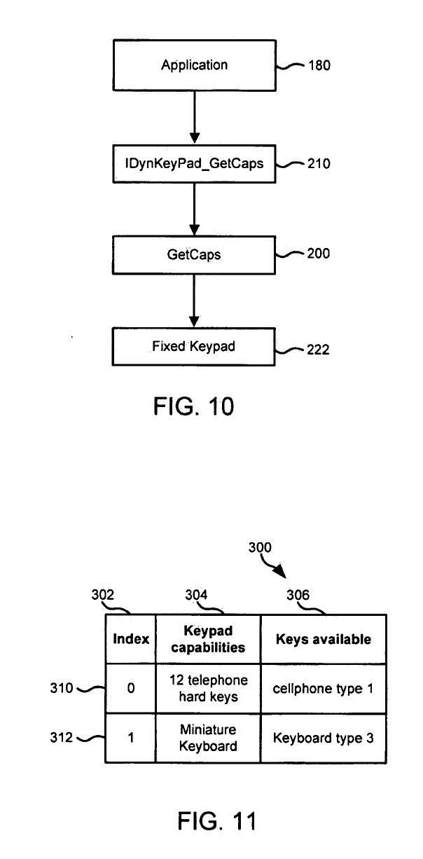

The process steps illustrated in FIG. 8 may be implemented in a number of electronic messages passed among the different hardware and software layers in the mobile device 10, such as illustrated in FIG. 9. Upon activation or during operation, an application 180 may request information regarding the keypads that are activated and available on the mobile device, such as by issuing a Keypad_Query API, message 210a. The application may communicate directly with the runtime environment, message 210a, which forwards the Keypad_Query API to the keypad protocol 100, message 210b. In some implementations, the application 180 may transmit the Keypad_Query API directly to the keypad protocol 100 without involving the runtime environment layer 170. In response to receiving the Keypad_Query, the keypad protocol 100 transmits the available keypad(s) and their capabilities, message 212a. This may be transmitted to the runtime environment layer 170 which transmits the information onto the application 180, message 212b. In some implementations, the keypad protocol 100 may communicate directly with the application 180, bypassing the runtime environment layer 170. As discussed above with reference to FIG. 8, receipt of the Keypad_Query may prompt the keypad protocol 100 to query the attached keypads, message 200.

Using information received from the keypad protocol 100, the application 180 may send keypad configuration information and, optionally, graphics files to the keypad protocol 100, messages 220, 224. As with other messages, this information may be sent by way of the runtime environment layer 170 or directly to the keypad protocol 100 as illustrated. The application 180 may also provide graphics files to the display layer, message 234, to present a display consistent with the application and functions assigned to various keys.

Using the keypad configuration and graphics files provided by the application 180, the keypad protocol 100 may configure a key translation table, process 226, and configure the keypad, message 230. Additionally, the keypad protocol 100 may provide some keypad display files to the display, message 228. For example, if the keypad includes configurable keys (e.g., keys 22-24 illustrated in FIG. 1), the keypad protocol 100 may inform the display of the label to present above those keys. Alternatively the application 180 may provide the label presented above the configurable keys 22-24 in its display message 234.

The processing illustrated in FIGS. 8 and 9 may also be initiated whenever a new keypad is activated on the mobile device 10. For example, an application 180 that is running, and thus has already configured a one keypad, may be notified by system software that a new keypad has been activated on the mobile device, such as by a user sliding or rotating a miniature keyboard into the operating position as provided on some multifunction cell phones currently available. As noted above, such a second keyboard may be activated (i.e., configured so that it can receive user inputs) when the keyboard is deployed (i.e., moved into an operating position). This notification that a second keypad has been activated may be in the form of an interrupt communicated to the application 180 by system software, or a system flag set in memory which the application may occasionally check. When an application 180 learns that another keypad has been activated, the application may again call the Keypad_Query API, step 210, in order to receive information regarding the capabilities of the newly activated keypad. The application may then select and configure the newly activated keypad, step 220, in the manner described above with reference to FIG. 8. Thus, keypads may be activated on the mobile device 10 at any point during the operation of an application 180. For example, an application 180 may be started before a particular keypad is activated. Upon activation, the application configures an available and active keypad for the application's functions. Then, when a user activates a second keypad better suited to the particular application, the application 180 can select the newly activated keypad and continue operations using user inputs received from that keypad. In this manner, the keypad protocol 100 facilitates the configuration of keypads in a flexible manner, enabling the key function reveal embodiments to be implemented without adding complexity to applications.

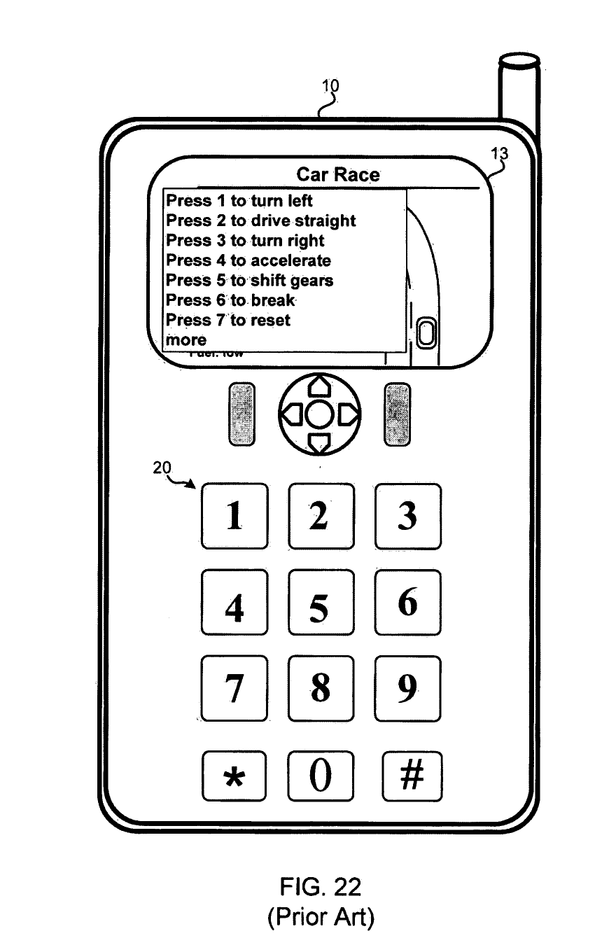

Applications may also interface with the keypad protocol 100 in order to obtain more information about particular keypads that may be useful in making a selection. In mobile devices that include two or more keypads or user interfaces, such as a telephone keypad used for telephone applications and a miniature keyboard used for text and e-mail applications, an application 180 may need to select one of those keypads for receiving user inputs based upon the application functionality. For example, an application involving significant text entry, such as messaging or e-mail application, may be best supported by a miniature keyboard if such a keypad is available and active on the mobile device, while an media player or game may be best supported by a telephone keypad (see FIGS. 19-25 for example) since only a few keys are used by the application.

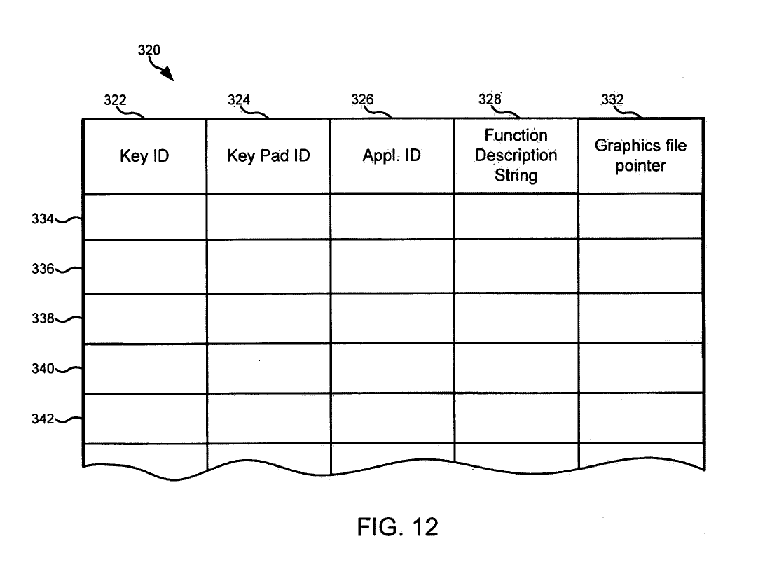

An example process by which the application 180 may obtain information regarding the capabilities of a particular keypad are illustrated in FIG. 10. The application 180 may issue a request for the capabilities of a particular keypad by identifying the keypad index and requesting its capabilities, such as by means of an API 210 (e.g., IDynKeyPad_GetCaps). For example, if a mobile device has two keypads, one may be identified with the index “0” while the other is identified by the index “1” as illustrated in FIG. 11. In response to receiving such an API, the keypad protocol 100 may request the capabilities from the keypad driver 110 associated with the keypad ID, step 200, if the keypad protocol does not already have that information in memory (e.g., in a data table like that illustrated in FIG. 11). The keypad protocol 100 may then provide the received capabilities information to the application, step 220. In the illustrated example, the application has asked for the capabilities of a particular keypad and is informed that the selected keypad is a fixed keypad.

Information regarding the available keypad capabilities may be provided to applications by the keypad protocol 100 in a standardized data format, such as illustrated in FIG. 11. The identification and capabilities of a particular keypad may be transmitted in a data record packet 310, 312 including an index 302 or code identifying the keypad, a summary of the keypad capabilities 304, an identification of the keys available in the keypad 306. A separate data record packet may be transmitted for each available keypad, such as data records 310, 312. Alternatively, the keypad protocol 100 may transmit the keypad capabilities data table 300 including data records 310, 312 for each available keypad, with each data record including data fields 302 through 306 providing the identification and capabilities of the associated keypad. The data structure illustrated in FIG. 11 is provided as an example and is not intended to limit in any way the data format or information that may be provided by the keypad protocol to an application.

The keypad information provided to the application 180 may be in the form of a standardized key set identifier and may use standardized keypad definitions to communicate the particular type of keypad and its capabilities. Alternatively, the keypad capabilities data table 300 may list individual keys that are available and their individual capabilities and configurations. The entries shown in the keypad capabilities table 300 are provided for illustrative purposes only and in a typical implementation are more likely to store data in the form of binary codes that can be recognized and understood by an application 180.

Applications 180 may provide a variety of data and configuration parameters to the keypad protocol 100 for use in interpreting key touch and keypress events and in translating those events into signals or data structures which the application 180 can process. An example of a data structure for storing such information for use by the keypad protocol 100 is illustrated in FIG. 12. Such a data structure 320 may be composed of any number of data records 334-342 associated with each key on the available keypads. For ease of reference, a first data field 322 may include a key ID that the keypad protocol 100 can use to identify individual keys being touched, nearly touched or pressed. This key ID may be communicated to the keypad driver 110 associated with a particular keypad 120 so that the driver and the keypad protocol 100 communicate regarding key press events using the same key ID. A second data field 324 may include a keypad ID that the keypad protocol 100 can use to distinguish key events among various activated keypads. The key patent ID data field 324 may include a simple serial listing of attached keypads (e.g., 0, 1, 2 etc.). Alternatively, the keypad ID data field 324 may store a globally unique keypad ID assigned to keypad models or individual keypads by the keypad supplier or the original equipment manufacturer (OEM). For example, the keypad ID could be the MAC ID assigned to the keypad by the OEM. Regardless, the combination of the keypad ID and the key ID can be used to uniquely identify each key touch and keypress event. The data structure 320 may also include information provided by an application using a particular keypad, such as an application key ID 326 and a text string containing a description of the assigned function. Such information may be provided by the application 180 to inform the keypad protocol 100 of the particular key ID that the application 180 needs to receive in response to a particular key press event. Thus, an application 180 may define an arbitrary set of key IDs that it uses in its functions and provide those arbitrary key IDs to the keypad protocol 100 so that the protocol can properly inform the application 180 of particular key press events. In this manner, application software can be written to function with standard processes even though keypad layouts and particular keys vary from keypad to keypad, with the keypad protocol 100 providing the necessary translation. The functional description string 328 can be used by the keypad protocol 100 to generate text key function reveal display in response to a key touch event.

The keypad translation data structure 320 may also include graphics (data field 332) associated with the function assigned to a key. The application 180 may provide graphic files to be displayed in response to a key touch event in order to graphically illustrated the key functionality assigned by the application. The graphics file 332 can be used by the keypad protocol 100 to generate a graphic key function reveal display in response to a key touch event. Rather than store the graphics within the keypad translation data structure 320, the data field may include a pointer (i.e., memory address) to the memory location storing the graphic file associated with the particular key. Such graphics may be in the form of simple symbols that communicate a particular key function, such as arrows (left, right, up, down or curved), circles, mathematical operation symbols, etc.

To configure keypads using the keypad protocol 100, an application 180 need only provide some of the information to be stored in the keypad translation data structure 320 in the form of a series of data records. Such data records may be linked to standard key identifiers that the keypad protocol can recognize. For example, if the keypad being configured is a standard 12 key numeric keypad, the application 180 may identify a key by its standard numeral value. Using that identifier, the application 180 can provide the application identifier key ID that the keypad protocol 100 can use to inform the application of a key press event, along with the function description string and/or function graphic or file pointer. The keypad protocol 100 can receive such data records and store them in a data table such as illustrated in FIG. 12.

One of skill in the art will appreciate that keypad translation and configuration data may be stored in memory in a variety of different data structures. The data structure illustrated in FIG. 12 is for example purposes only and is not intended to limit the scope of the disclosure or claims in any way.

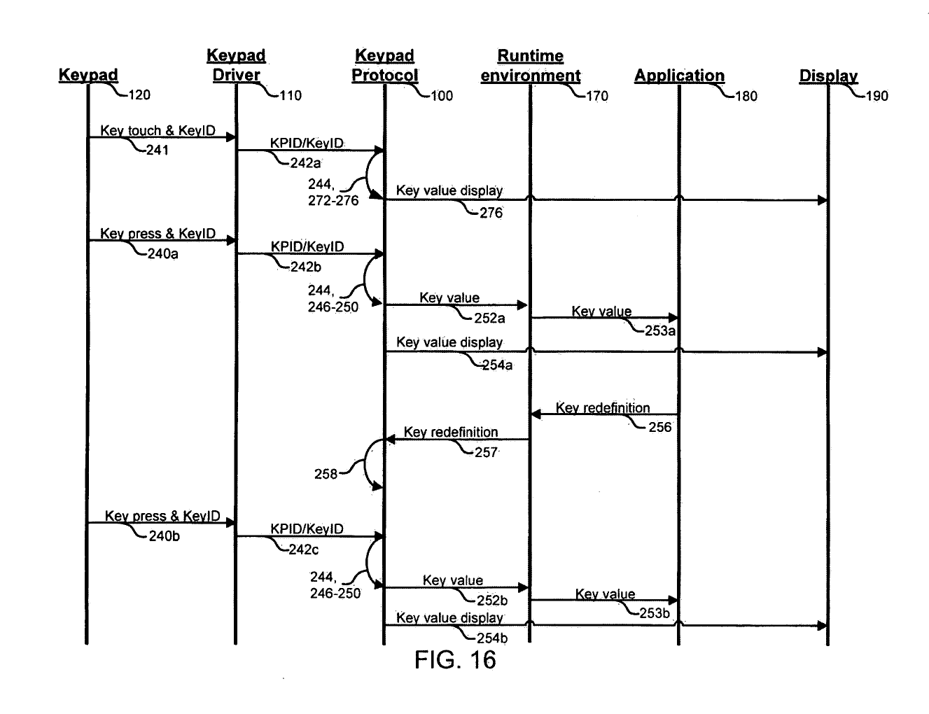

Processing flow of key touch and key press events are illustrated in FIG. 13. When a key is touched, nearly touched or pressed, the event is detected by the keypad hardware 120, which signals the keypad driver software 110. The keypad driver 110 then informs the keypad controller 104 portion of the keypad protocol 100 of the key touch or keypress event. This may be accomplished directly, such as by a signal sent to the keypad controller 104, or indirectly, such as by setting a callback flag or an interrupt that the system software will recognize periodically and request the key touch or keypress event information to be provided by the keypad driver.

When a key is touched, nearly touched or pressed on the keypad 120, the key circuitry and its keypad driver 110 can inform the keypad protocol 100 of the event in a variety of ways, such as by providing an interrupt, or storing data in a particular register or portion of memory used for setting system flags. For example, as illustrated in FIG. 14, a simple data structure 350 may be stored in memory to indicate that a key has been touched, nearly touched or pressed along with the key ID of the pressed key. For example, such a data structure may include two or more flags 352, 354 that the keypad protocol can periodically check to determine if a key press touch or keypress event has occurred. The first flag 352 may indicate when set (i.e., a “1” is stored in the memory field 352) that a key touch or press event has occurred and that a corresponding key ID is stored in a particular memory field, such as data field 356. The second flag 354 may indicate by its setting whether the event is a key touch event (e.g., indicated by a “0” stored in the memory field 354) or a keypress event (e.g., indicated by a “0” stored in the memory field 354). In order to uniquely identify a key press event among a plurality of keypads, the key ID may be stored in the key ID data field 356 in conjunction with a keypad ID or index data field 358. Additional flags may be set to indicate other information concerning the key press event. For example, a flag (e.g., flag 354) may be set to indicate when the key press event includes a simultaneous touch, near touch, or press of another key, such as a “shift,” “control,” or “alt” key as may be presented on a miniature keyboard. As another example, another flag may be set to indicate that the key press event was not preceded by a key release, indicating that the key is being held down for an extended duration. Any number of additional flags and data fields may be included in the interrupt, register or data structure to communicate information regarding the key touch or keypress event that can be interpreted by the keypad protocol 100.

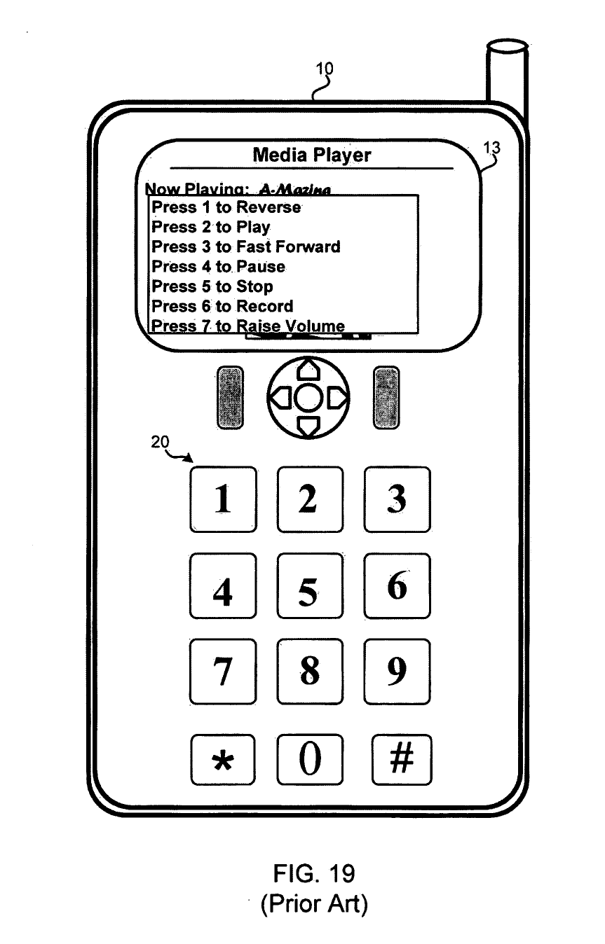

When the keypad protocol 100 is informed of a key touch event, it can translate the key touch event information into a functional description that can be presented in the key function reveal portion of the display. Similarly, when the keypad protocol 100 is informed of a keypress event, it can translate the key press event into information that an application can interpret. An example of method steps that may be implemented by the keypad protocol 100 in receiving a key touch event and a keypress event are illustrated in FIG. 15. As discussed above, when a key is pressed, the event is sensed by the keypad hardware and signaled to the associated keypad driver, step 240. Similarly, when a key is pressed, the event is sensed by the keypad hardware and signaled to the associated keypad driver, step 241. The keypad driver translates the key touch or keypress event into a signal, interrupt, stored data (e.g., described above with reference to FIG. 14) or other form of information and provided to the keypad protocol, step 242. Upon receiving a key touch or keypress event signal from the keypad driver 110, the keypad protocol 100 may retrieve from memory or from the signal provided by the keypad driver one or more flag values distinguishing the event as a key touch or keypress event, along with the keypad ID and key ID, step 244. The keypad protocol 100 may then test a flag value (e.g., flag 354 for example) to determine whether the event should be processed as a touch event or a press event, test 245.

If the event is determined to be a keypress event in test 245, the keypad protocol 100 can locate the corresponding data record within the key translation table 320 using the key ID and keypad ID, step 246. Using the data stored in the corresponding data record, the keypad protocol 100 can retrieve the application ID specified by the application 180 corresponding to the particular keypress event, step 248. Using that information, the keypad protocol can create a notification object for communication to the application 180, step 250. Finally, the keypad protocol sends the keypress notification object to the application 180, step 252. In sending the notification object, the keypad protocol 100 may send the object directly to the application 180 or by way of the operating system or runtime environment 170.

If the event is determined to be a key touch event in test 245, the keypad protocol 100 can locate the corresponding data record within the key translation table 320 using the key ID and keypad ID, step 272, and retrieve the function description text or graphic information associated with the key, step 274. Using that text or graphic information, the keypad protocol can format a display or generate a display object for presentation within the key function reveal window within the display, step 276. Finally, the keypad protocol 100 sends the key function reveal text/graphic or display object to the display, step 278. In sending the key function reveal text/graphic or display object to the display, the keypad protocol 100 may send the information directly to the display or may provide the information to a display layer which configures and manages the generation of images on the display.

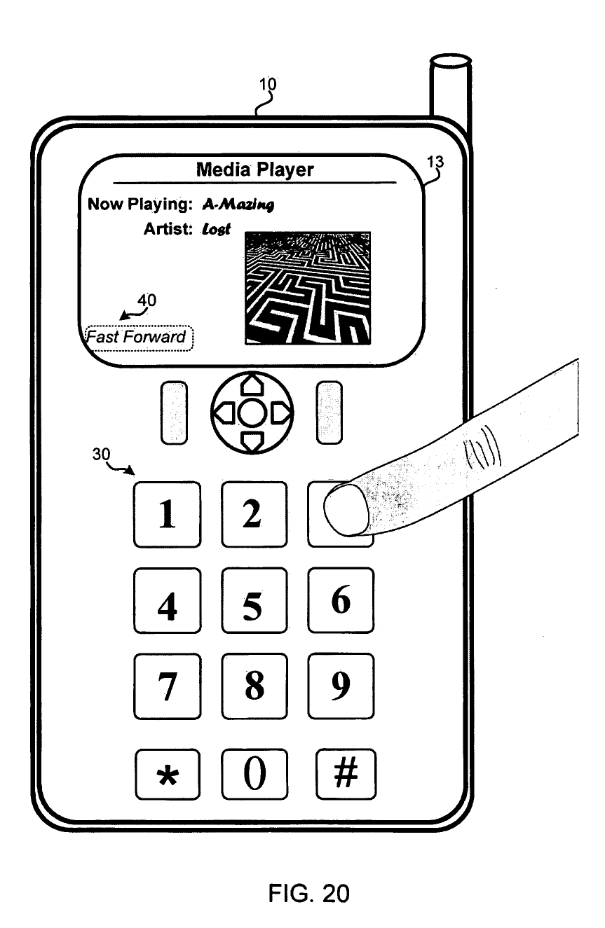

The process of receiving and processing a key press event may be accomplished in a series of messages among the different hardware and software layers in the mobile device 10 as illustrated in FIG. 16.

When a key is touched or nearly touched, the keypad will send a key touch event signal to the keypad driver, message 241. In turn the keypad driver sends a key touch event flag along with the keypad ID and key ID to the keypad protocol, message 242a. As discussed above, this message may be in the form of information that is saved to a memory location that the keypad protocol may periodically access or access upon detecting a set flag or upon receiving an interrupt. Using this information, the keypad protocol generates the key touch notification object, processing steps 244 and 272-276, and then transmits a key function reveal text or graphic to the display, message 276.

When a key is pressed, the keypad will send a key press event signal to the keypad driver, message 240a. In turn the keypad driver sends the keypad ID and key ID to the keypad protocol, message 242b. As discussed above, this message may be in the form of information that is saved to a memory location that the keypad protocol may periodically access or access upon detecting a set flag or upon receiving an interrupt. Using this information, the keypad protocol generates the key press notification object, processing steps 244 and 246-250, and then transmits the key value to the runtime environment, message 252a, for relay to the application 180 in message 253a. Alternatively, the keypad protocol may communicate the key value directly to the application 180. Additionally, the keypad protocol 100 may send a key value or graphic to the display, message 254a, so the display can reflect the key press event (e.g., presenting on the display the value of the key that was pressed).

A subsequent key press event will be handled in the same way, as illustrated in messages 240b through 254b in FIG. 16. Thus, with each key press event, the keypad protocol 100 receives messages from a keypad driver 110 and provides the translated key value information to the application 180 and display.

In some situations, a key press event may prompt an application 180 to redefine key values or functions for subsequent key presses. For example, if the application 180 is a media player, such as an MP3 player, and a first key press event is interpreted by the application as initiating audio play (i.e., the first key press had a “play” function), the application may change the functionality of the same key so that a subsequent press will be interpreted as pausing or stopping the media play (i.e., the second key press will have a “stop” function). FIG. 16 reflects this potential by illustrating that the application 180 may send a key redefinition command (i.e., new configuration information) to the keypad protocol 100, message 256. This message may be relayed by the runtime environment layer 170 to the keypad protocol 100 with a similar key redefinition message 257. Upon receiving a key redefinition message, the keypad protocol 100 may reconfigure the key translation table 320 to reflect the changed key configuration information, process 258. Then subsequent key touch events communicated to the keypad protocol in messages 241 and 242a will be interpreted by the keypad protocol 100 according to the revised key translation table 320, processing steps 246-250b, so that the redefined function will be presented in the key function reveal display, message 276. Similarly, subsequent key press events communicated to the keypad protocol in messages 240b and 242b will be interpreted by the keypad protocol 100 according to the revised key translation table 320, processing steps 246-250b. The redefined key value or function will be transmitted to the application in messages 252b and 253b. Also, the redefined key value may be sent to the display, message 254b.

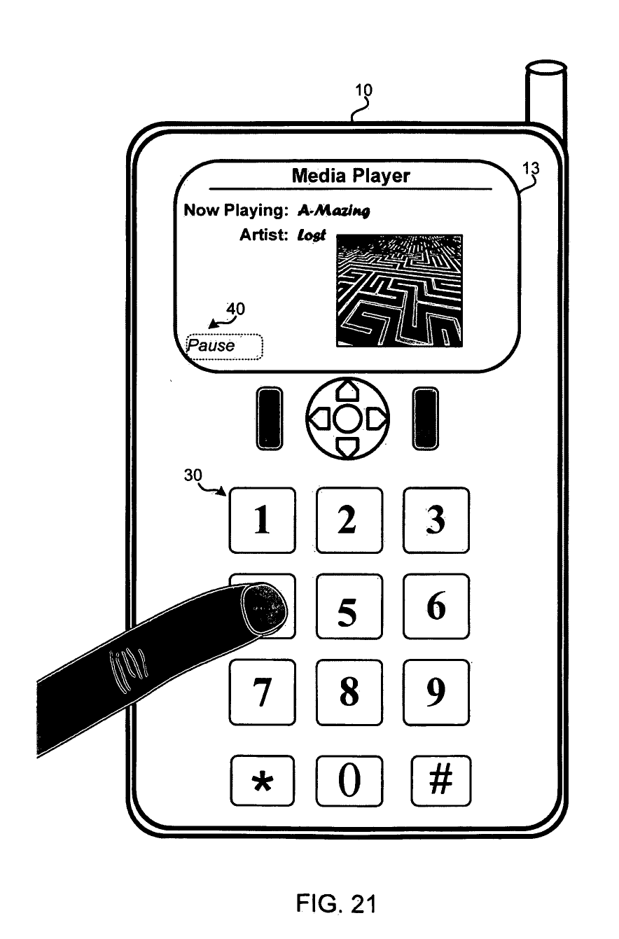

The advantages of the various embodiments may be further explained by way of some examples which are illustrated in FIGS. 17 through 25. Referring to FIG. 17, a mobile device 10 can be a cell phone with the display keys 402 displaying numbers 0-9 as may be appropriate for many users. Such a keypad typically includes three or four letters associated with selected keys, as may be useful in entering text (e.g., for entering an SMS message). By touching or nearly touching a key (e.g., “2” key as illustrated in FIG. 17), a user can be quickly informed of the value of the key in the key function reveal window 40 of the display 13. However, if users speak and read a language that uses non-Western numerals and letters, they may select to have the numbers and letters associated with keys presented in a different alphabet. Such a change can be easily implemented using the various embodiments, with each key's assigned value(s) revealed in the selected alphabet and/or numerals in the key function reveal window 40 with a touch or near touch of the key as illustrated in FIG. 18. In embodiments without a keypad protocol 100, the different alphabet and/or numerals are implemented within the application software. However, the presentation of key values in a different script in response to a touch or near touch of the key can be accomplished using the keypad protocol embodiments without the need to substantially change the application software (e.g., a telephone application) operating on the mobile device 10. The change can be accomplished simply by storing a different set of key graphics in the key translation table 320, for example. Such a mobile device may be more useful in some parts of the world where numerals are presented in a different format.

In the foregoing embodiments, the key function reveal display may be maintained on the display so long as the key remains touched or nearly touched. Alternatively, the key function reveal display may be maintained for a preset duration following a key touch or near touch, even if the user stops touching the key before the preset duration or continues to touch or near touch the key beyond the preset duration. To accomplish this alternative implementation, a key touch event may also initiate a timer which determines how long the key function reveal display remains.

The flexibility and usefulness of the various embodiments are particularly evident when the mobile device is operating applications which can utilize a non-alphabetic user-interface in order to make the operation of the application more intuitive to a user. For example, FIG. 19 illustrates a mobile device 10 executing a media player application without the benefits of the various embodiments. In a media player an application, keypads may be configured to receive user commands associated with the media player functions, such as controlling volume, playing, stopping or rewinding the media, etc. In a mobile device with fixed keys 20, the media player application must assign a function to various keys. In order to inform the user of the key assignments, a display may be presented which associates keys with various application functions. In the illustrated example, the key menu is presented in the mobile device display 13. As this illustration shows, the display of key functions takes up a significant amount of the display 13 area, thus reducing the amount of information regarding the media that can be displayed at the same time. Consequently, in such applications users are expected to memorize the key function assignments, with a key function menu recallable when needed.

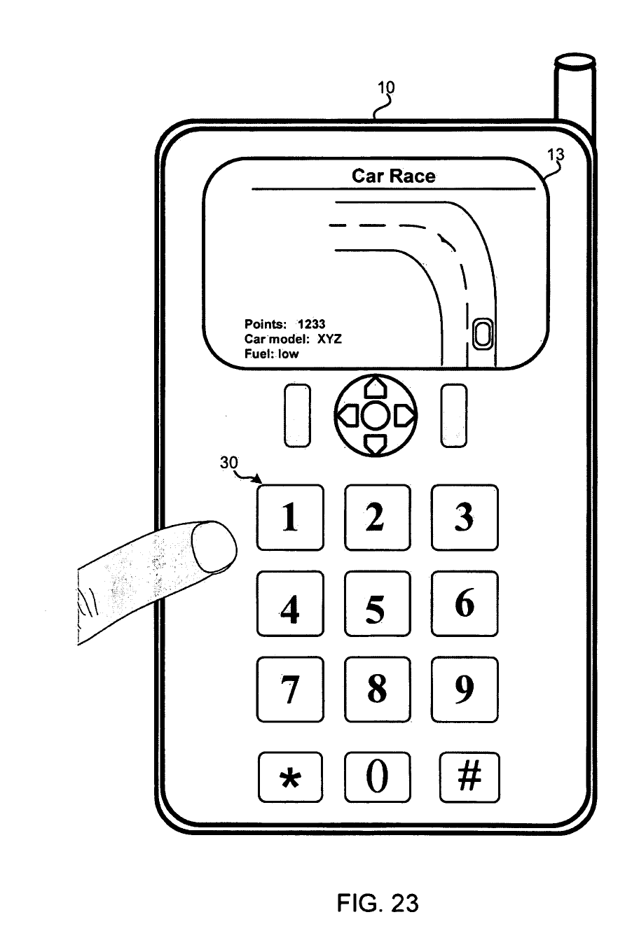

Using the various embodiments, users can be informed of the functions assigned to various keys without having to call up a menu that blocks the display 13, as illustrated in FIGS. 20 and 21. Users simply need to touch or near touch a key on a touch-sensitive keypad 30 to see the currently assigned function in the key function reveal window 40 of the display 13. In the example illustrated in FIG. 20, a user touching or nearly touching the “3” key prompts the mobile device 10 to display the assigned function “Fast Forward” in the key function reveal window 40 of the display 13. Similarly, in the example illustrated in FIG. 21, a user touching or nearly touching the “4” key prompts the mobile device 10 to display the assigned function “Pause” in the key function reveal window 40 of the display 13. A touch-sensitive keypad and the embodiment methods, users can be informed about the function assigned to keys without blocking the media player display as illustrated in FIGS. 20 and 21. Instead of revealing the assigned function as text (i.e., “Fast Forward” or “Pause”), the function may be revealed graphically, such as a double arrow for Fast Forward or two vertical bars for “Pause.”

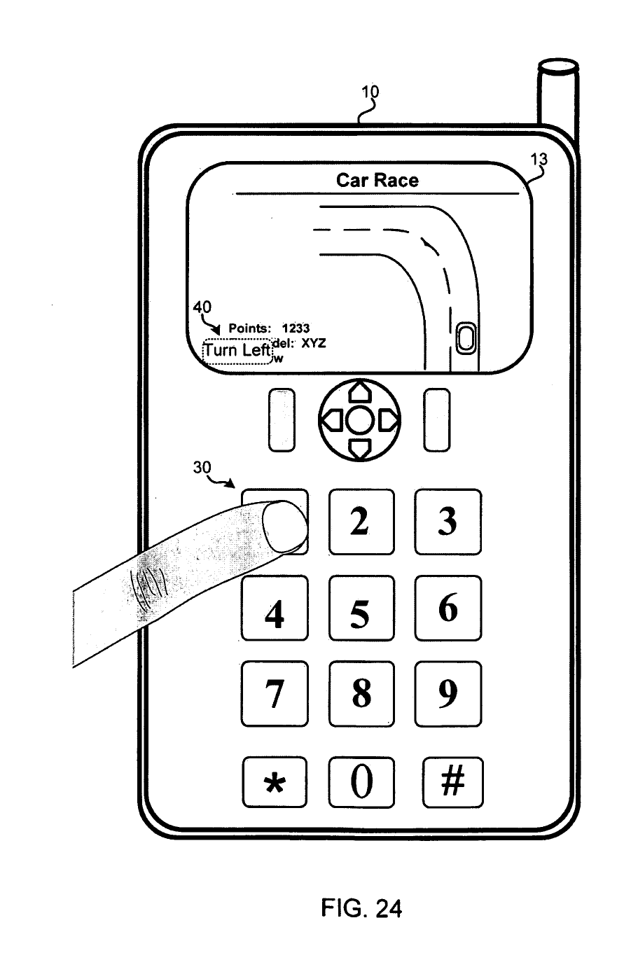

FIGS. 22 through 25 illustrate another example involving a game application. Referring to FIG. 22, a game application operating on a mobile device 10 having conventional fixed-label keys will need to provide a menu mapping key functions to particular conventional keys 20 as shown in the display 13. Users are expected to memorize the key functions since the function menu will occupy too much of the display 13 to allow simultaneous game play.

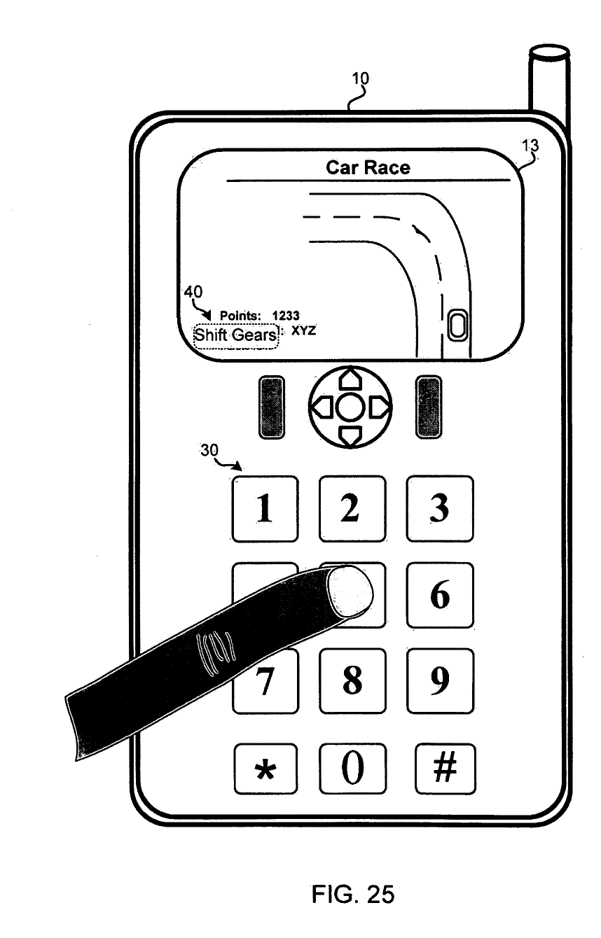

Using the various embodiments, users can be informed of the game functions assigned to various keys without having to call up a menu that blocks the display 13, as illustrated in FIGS. 23-25. Without the need to present a menu of assigned key functions, the entire display 13 can be used to present game graphics as illustrated in FIG. 23. Users can be informed of the game functions assigned to keys simply by touching or nearly touching a key on the touch-sensitive keypad 30 to see the currently assigned function in the key function reveal window 40 of the display 13. In the example illustrated in FIG. 24, a user touching or nearly touching the “1” key prompts the mobile device 10 to display the assigned function “Turn Left” in the key function reveal window 40 of the display 13. Similarly, in the example illustrated in FIG. 25, a user touching or nearly touching the “5” key prompts the mobile device 10 to display the assigned function “Shift Gears” in the key function reveal window 40 of the display 13.

The various embodiments may be implemented by the processor 11 executing software instructions configured to implement one or more of the described methods. Such software instructions may be stored in memory 12 as the device's operating system software, a series of APIs implemented by the operating system, or as compiled software implementing an embodiment method. Further, the software instructions may be stored on any form of tangible processor-readable memory, including: a random access memory 12, a memory module plugged into the mobile device 10, such as an SD memory chip, an external memory chip such as a USB-connectable external memory (e.g., a “flash drive”), read only memory (such as an EEPROM); hard disc memory, a floppy disc, and/or a compact disc.

Those of skill in the art would appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The steps of a method or algorithm described in connection with the embodiments disclosed herein may be embodied directly in hardware, in a software module executed by a processor, or in a combination of the two. A software module may reside in processor readable memory which may be any of RAM memory, flash memory, ROM memory, EPROM memory, EEPROM memory, registers, hard disk, a removable disk, a CD-ROM, or any other form of storage medium known in the art. An exemplary storage medium is coupled to a processor such that the processor can read information from, and write information to, the storage medium. In the alternative, the storage medium may be integral to the processor. The processor and the storage medium may reside in an ASIC. The ASIC may reside in a user terminal or mobile device. In the alternative, the processor and the storage medium may reside as discrete components in a user terminal or mobile device. Additionally, in some aspects, the steps and/or actions of a method or algorithm may reside as one or any combination or set of codes and/or instructions on a machine readable medium and/or computer readable medium, which may be incorporated into a computer program product.

The foregoing description of the various embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein, and instead the claims should be accorded the widest scope consistent with the principles and novel features disclosed herein.

What is claimed is:

1. A method for revealing a function assigned to a key by an application operating on a computing device, comprising:
sensing a touch or near touch of the key and generating a key touch event signal;
determining a key value or function assigned by the application to the key associated with the key touch or near touch; and
presenting a display of the assigned key value or function.

2. The method of claim 1, further comprising:
receiving a keypad configuration instruction from the application in a keypad protocol;
receiving the key touch event signal in the keypad protocol; and
determining the key value or function assigned by the application to the key using the received keypad configuration instruction in the keypad protocol,
wherein the keypad protocol formats the presentation of the display of the assigned key value or function.

3. The method of claim 2, further comprising storing the keypad configuration instruction in a keypad translation table, wherein the key value or function assigned to the key is determined using the keypad translation table.

4. The method of claim 2, further comprising:
storing a list of activated keypads connected to the computing device;
informing the application of activated keypads connected to the computing device; and
receiving in the keypad protocol a keypad selection from the application.

5. The method of claim 4, further comprising informing the application of keypad capabilities.

6. The method of claim 2, further comprising:
receiving in the keypad protocol a request for available keypads from the application;
informing the application of activated keypads connected to the computing device in response to the request received from the application; and
receiving in the keypad protocol a keypad selection from the application.

7. The method of claim 3, further comprising:
receiving in the keypad protocol a graphic from the application related to a key; and
presenting the graphic when presenting a display of the assigned key value or function.

8. The method of claim 1, wherein the computing device is a mobile device.

9. The method of claim 1, wherein the computing device is a cellular telephone.

10. A computing device, comprising:
a processor;
a display coupled to the processor;
a touch sensitive keypad coupled to the processor, the keypad including a key; and
a memory coupled to the processor,
wherein the processor is configured with software instructions to perform steps comprising:
sensing a touch or near touch of the key and generating a key touch event signal;
determining a key value or function assigned by an application to the key associated with the key touch or near touch; and
displaying the assigned key value or function on the display.

11. The computing device of claim 10, wherein the processor is configured with software instructions to perform steps further comprising:
receiving a keypad configuration instruction from the application in a keypad protocol;
receiving the key touch event signal in the keypad protocol; and
determining the key value or function assigned by the application to the key using the received keypad configuration instruction in the keypad protocol,
wherein the keypad protocol formats the presentation of the assigned key value or function on the display.

12. The computing device of claim 11, wherein the processor is configured with software instructions to perform steps further comprising storing the keypad configuration instruction in a keypad translation table, wherein the key value or function assigned to the key is determined using the keypad translation table.

13. The computing device of claim 11, wherein the processor is configured with software instructions to perform steps further comprising:
storing a list of activated keypads connected to the computing device;
informing the application of activated keypads connected to the computing device; and
receiving in the keypad protocol a keypad selection from the application.

14. The computing device of claim 13, wherein the processor is configured with software instructions to perform steps further comprising informing the application of keypad capabilities.

15. The computing device of claim 11, wherein the processor is configured with software instructions to perform steps further comprising:
receiving in the keypad protocol a request for available keypads from the application;
informing the application of activated keypads connected to the computing device in response to the request received from the application; and
receiving in the keypad protocol a keypad selection from the application.

16. The computing device of claim 12, wherein the processor is configured with software instructions to perform steps further comprising:
receiving in the keypad protocol a graphic from the application related to a key; and
presenting the graphic when presenting the assigned key value or function on the display.

17. The computing device of claim 10, wherein the computing device is a mobile device.

18. The computing device of claim 10, wherein the computing device is a cellular telephone.

19. A tangible storage medium having stored thereon processor-executable software instructions configured to cause a processor of a computing device to perform steps comprising:
sensing a touch or near touch of a key and generating a key touch event signal;
determining a key value or function assigned by the application to the key associated with the key touch or near touch; and
presenting a display of the assigned key value or function.

20. The tangible storage medium of claim 19, wherein the tangible storage medium has processor-executable software instructions configured to cause a processor of a computing device to perform further steps comprising:
receiving a keypad configuration instruction from the application in a keypad protocol;
receiving the key touch event signal in the keypad protocol; and
determining the key value or function assigned by the application to the key using the received keypad configuration instruction in the keypad protocol,
wherein the keypad protocol formats the presentation of the display of the assigned key value or function.

21. The tangible storage medium of claim 20, wherein the tangible storage medium has processor-executable software instructions configured to cause a processor of a computing device to perform further steps comprising storing the keypad configuration instruction in a keypad translation table, wherein the key value or function assigned to the key is determined using the keypad translation table.

22. The tangible storage medium of claim 20, wherein the tangible storage medium has processor-executable software instructions configured to cause a processor of a computing device to perform further steps comprising:
storing a list of activated keypads connected to the computing device;
informing the application of activated keypads connected to the computing device; and
receiving in the keypad protocol a keypad selection from the application.

23. The tangible storage medium of claim 22, wherein the tangible storage medium has processor-executable software instructions configured to cause a processor of a computing device to perform further steps comprising informing the application of keypad capabilities.

24. The tangible storage medium of claim 20, wherein the tangible storage medium has processor-executable software instructions configured to cause a processor of a computing device to perform further steps comprising:
receiving in the keypad protocol a request for available keypads from the application;
informing the application of activated keypads connected to the computing device in response to the request received from the application; and
receiving in the keypad protocol a keypad selection from the application.

25. The tangible storage medium of claim 21, wherein the tangible storage medium has processor-executable software instructions configured to cause a processor of a computing device to perform further steps comprising:
receiving in the keypad protocol a graphic from the application related to a key; and
presenting the graphic when presenting a display of the assigned key value or function.

26. The tangible storage medium of claim 20, wherein the tangible storage medium is readable by a mobile device processor and the storage medium has processor-executable software instructions configured to be executed on the mobile device processor.

27. The tangible storage medium of claim 28, wherein the tangible storage medium is readable by a cellular telephone processor and the storage medium has processor-executable software instructions configured to be executed on the cellular telephone processor.

28. A computing device, comprising:
means for sensing a touch or near touch of the key and generating a key touch event signal;
means for determining a key value or function assigned by the application to the key associated with the key touch or near touch; and
means for presenting a display of the assigned key value or function.

29. The computing device of claim 28, further comprising:
means for receiving a keypad configuration instruction from the application in a keypad protocol;
means for receiving the key touch event signal in the keypad protocol; and
means for determining the key value or function assigned by the application to the key using the received keypad configuration instruction in the keypad protocol,
wherein the keypad protocol formats the presentation by the means for presenting a display of the assigned key value or function.

30. The computing device of claim 29, further comprising:
means for storing the keypad configuration instruction in a keypad translation table, wherein the key value or function assigned to the key is determined using the keypad translation table.

31. The computing device of claim 29, further comprising:
means for storing a list of activated keypads connected to the computing device;
means for informing the application of activated keypads connected to the computing device; and
means for receiving in the keypad protocol a keypad selection from the application.

32. The computing device of claim 31, further comprising:
means for informing the application of keypad capabilities.

33. The computing device of claim 29, further comprising:
means for receiving in the keypad protocol a request for available keypads from the application;
means for informing the application of activated keypads connected to the computing device in response to the request received from the application; and
means for receiving in the keypad protocol a keypad selection from the application.

34. The computing device of claim 30, further comprising:
means for receiving in the keypad protocol a graphic from the application related to a key; and
means for presenting the graphic when presenting a display of the assigned key value or function.

35. The computing device of claim 28, wherein the computing device is a mobile device.

36. The computing device of claim 28, wherein the computing device is a cellular telephone.
